(19) United States
(12) Patent Application Publication
(10) Pub. No.: US 2004/0241573 A1
(43) Pub. Date: Dec. 2, 2004

(54) Thermally sensitive, white light safe mask for use in flexography

(76) Inventors: Kevin Barry Ray, Fort Collins, CO (US); John Kalamen, Loveland, CO (US)

Correspondence Address: Paul W. Busse, FAEGRE & BENSON LLP, 2200 Wells Fargo Center, 90 South Seventh Street, Minneapolis, MN, 55402-3901, US

(21) Appl. No.: 10/452,750

(22) Filed: Jun. 2, 2003

(51) Int. Cl. G03F 9/00; G03F 7/00; G03F 7/26; B44C 1/00; G03C 1/76

(52) U.S. Cl. 430/270.1; 430/5; 430/302; 156/240

(57) ABSTRACT

The present invention provides a thermally imageable film having at least one thermally degradable binder, at least one infrared absorber, and additives. The thermally imageable film is transparent and remains transparent when exposed to white light wavelengths of about 390 to 750 nm or ultraviolet light wavelengths of about 190 to 390 nm. Upon imagewise exposure to infrared thermal radiation, the thermally imageable film forms an opaque area at the point of contact with the IR thermal radiation, the opaque areas of the film being ultraviolet light impermeable. The present invention also provides for a mask precursor or a relief printing plate precursor where the thermally imageable layer is coated directly onto a substrate as well as a method of making a mask or a relief printing plate using the thermally imageable film.

### FIELD OF THE INVENTION

This invention relates to a film, which becomes opaque when thermally exposed, to generate a pattern or image. The film can serve as a mask in the preparation of relief printing plates.

### BACKGROUND OF THE INVENTION

Flexographic printing plates are used in letterpress printing, particularly on surfaces which are rough or soft and easily deformable, such as cardboard, paper, plastic films, and packaging materials. Flexographic printing plates can be prepared from printing plate precursors that include a photosensitive layer on a support or substrate. The photosensitive layer is imaged by exposure to ultraviolet and/or visible radiation (visible radiation is also referred to herein as white light) to provide a negative working printing plate precursor and then developed with a suitable developer leaving a printing relief, that can be used for flexographic printing.

Imaging of the photosensitive layer of the printing plate precursor with ultraviolet and/or visible radiation is typically carried out through a mask, which has clear and opaque regions. Imaging takes place in the regions of the photosensitive layer under the clear regions of the mask but does not occur in the regions of the photosensitive layer under the opaque regions of the mask. The mask is usually a photographic negative of the desired image. If corrections are needed in the final image, a new mask must be made. This is a time-consuming process. In addition, the mask may change slightly in dimension due to changes in temperature and humidity. Thus, the same mask, when used at different times or in different environments, may give different results and could cause registration problems.

Direct digital imaging of printing plate precursors, which eliminates the need for exposure through a separate mask, is becoming increasingly important in the printing industry. In direct digital imaging, a computer controlled laser scans and images the photosensitive layer of the printing plate precursor. However, it has not been practical to use lasers to image the photosensitive layer of flexographic printing plate precursors. Conventional photosensitive layers of flexographic printing plate precursors have low photosensitivity and most of these photosensitive materials used in flexographic printing plate precursors have their greatest sensitivity in the ultraviolet region of the spectrum. Further, the thickness of a flexographic printing plate precursor as compared to the thickness of a lithographic printing plate precursor requires longer exposure times, even with high-powered lasers. For example, a flexographic printing plate precursor may require about one hour of exposure to ultraviolet and/or visible radiation compared to about five minutes for a lithographic printing plate precursor. Moreover, economical and reliable ultraviolet lasers with high power are not readily available. Relatively inexpensive infrared (IR) lasers that have a useful power output, though, are readily available.

Flexographic printing plate precursors having a layer ablatable by infrared (IR) thermal radiation on top of the photosensitive layer have been used to retain the advantages of direct digital imaging. For example, U.S. Pat. No. 5,262,275 (Fan) describes a photosensitive flexographic printing plate precursor having a laser ablatable masking layer. This laser ablatable masking layer is capable of absorbing IR thermal radiation but does not absorb ultraviolet and/or visible radiation. The laser ablatable masking layer is coated over a barrier layer and a photopolymerizable layer. The laser ablatable masking layer is imagewise ablated using IR thermal radiation. The non-ablated areas of the laser ablatable masking layer form a mask image that blocks ultraviolet and/or visible radiation in the areas of the photopolymerizable layer where development with a developer solution is desired. The photosensitive flexographic printing plate precursor is then exposed to ultraviolet and/or visible radiation to cure the exposed areas of the photopolymerizable layer. The unexposed areas of the photosensitive flexographic printing plate precursor underneath the mask image are removed with a developer solution. The exposed areas of the photopolymerizable layer that were cured upon exposure to ultraviolet and/or visible radiation are not removed by the developer solution and thus a flexible relief image on the photosensitive flexographic printing plate is produced. U.S. Pat. No. 5,705,310 (Van Zoeren) describes a photosensitive flexographic printing plate precursor similar to that described in the Fan patent. The photosensitive flexographic printing plate precursor of Van Zoeren, however, also has a cover sheet for collecting material ablated from the mask layer during imagewise ablation with IR thermal radiation.

Ablation techniques have a disadvantage in that they produce solid debris that is hazardous and that requires wiping and collection of the debris to insure that it does not materially affect the desired image. Further, additional filtration systems may be required to prevent the debris from contaminating the optics of a platesetter. The ablation method also requires the photosensitive element to contain a barrier layer between the photopolymer layer and the infrared sensitive layer. This barrier layer complicates the manufacturing process for producing laser ablatable flexographic printing plate precursors. In addition, some of the of the ablatable layers require large amounts of expensive infrared absorbers.

U.S. patent application Ser. No. 10/282,994 (Ray, et al.) describes a printing plate precursor for direct digital printing having a masking layer that contains a thermally imageable vesicular composition. The thermally imageable vesicular composition includes a polymeric material and a compound that releases a gas when heated. The compound that releases a gas when heated is known as a sensitizer and includes a variety of diazo-compounds that liberate nitrogen when heated such as diazonium salts, quinonediazides, azides, and carbazides. Instead of using imagewise ablation to form a mask, the masking layer is exposed to heat using IR thermal radiation or a hot body, typically a conventional apparatus containing a thermal printing head, to form a vesicular image. Patterns of small bubbles or vesicles of gas entrapped in a polymeric material characterize vesicular images. Because the bubbles or vesicles have a refractive index that is very different from that of the polymeric material, they refract light, thereby forming the image. The inclusion of diazo-compounds, however, complicates handling of the printing plate precursor in the presence of white light and ultraviolet light.

Thus, a need exists for flexographic printing plate precursors that have the advantages of direct digital imaging but do not have the disadvantages associated with the conventional laser ablation processes described above and does not contain sensitizers such as diazo-compounds that limit the use of the flexographic printing plate precursor in white light and ultraviolet light conditions.

### SUMMARY OF THE INVENTION

In one embodiment, the present invention provides a thermally imageable film having at least one thermally degradable binder present in amounts of from 80 to 99.5 wt % and at least one infrared absorber present in amounts of from 0.5 to 20 wt %. Where desired, the present invention also includes additives.

This thermally imageable film is transparent and remains transparent when exposed to white light of wavelengths of about 390 to 750 nm or ultraviolet light of wavelengths of about 190 to 390 nm. Thus, the thermally imageable film is white light and ultraviolet light safe. Upon imagewise exposure to infrared (IR) thermal radiation, however, the thermally imageable film forms an opaque area at the point of contact with the IR thermal radiation, the opaque areas of the film having an optically density of from about 0.05 to about 5.0 and being impermeable to ultraviolet light for at least one minute. In other embodiments, the opaque areas of the film have optical densities of from about 0.05 to 4.0, from about 0.05 to 3.0, or from about 0.05 to 2.0. Further, in an alternative embodiment, the opaque area is impermeable to ultraviolet light for at least five minutes and in yet another embodiment the opaque area is impermeable to ultraviolet light for at least ten minutes. As used herein, IR thermal radiation also refers to IR laser radiation or laser thermal radiation.

In another embodiment, the present invention provides for a mask precursor wherein the thermally imageable film is coated onto a support or substrate from a solvent.

In yet another embodiment, the present invention provides for a relief printing plate precursor. In this embodiment, an ultraviolet light sensitive layer is coated onto a substrate. A thermally imageable film is then coated directly on the ultraviolet light sensitive layer. When the film is imagewise exposed with IR thermal radiation, opaque areas are formed on the thermally imageable film where the IR laser radiation contacts the thermally imageable film. The opaque areas are impermeable to ultraviolet light. The areas of the thermally imageable film that do not come in contact with the IR thermal radiation remain transparent.

The present invention also provides for a method of making a mask precursor that includes providing a substrate and coating a thermally imageable film on the substrate from a solvent.

In yet another embodiment, the present invention provides for a method of making a relief printing plate precursor that includes providing a substrate having an ultraviolet light sensitive layer and coating a thermally imageable film on the ultraviolet light sensitive layer from a solvent. After the thermally imageable film is imagewise exposed using IR thermal radiation to form opaque areas, the ultraviolet light sensitive layer is flood exposed to ultraviolet light wherein the ultraviolet light does not permeate through the opaque areas of the thermally imageable film. The exposed relief printing plate precursor is then developed to remove the areas of the ultraviolet light sensitive layer underneath the opaque areas of the thermally imageable layer and therefore not exposed to ultraviolet light. In a further embodiment of the present invention, the thermally imageable film is peeled away from the flood exposed relief printing plate precursor before the relief printing plate precursor is developed.

### DETAILED DESCRIPTION OF THE INVENTION

Unless the context indicates otherwise, in the specification and claims, the terms thermally degradable binder, infrared absorber, additives, solvent, developer and similar terms also include mixtures of such materials. Unless otherwise specified, all percentages are percentages by weight.

### Thermally Imageable Film

The thermally imageable film minimally includes at least one thermally degradable binder, at least one infrared (IR) absorber and additives depending on the final properties desired.

The thermally degradable binder, IR absorber and additives can be combined to produce a clear, non-cloudy mixture having a pale green to yellow hue that does not cause appreciable scattering of the radiation ultimately used for imaging. This mixture is then coated from an aqueous or organic solvent onto a substrate to provide a thermally imageable film that is transparent. The coating weight of the thermally imageable film is typically from about 1 to 10 g/m².

The coating weight, the amount and type of thermally degradable binder and IR absorber and the amount of imaging energy are selected to favor depolymerization of the thermally degradable binder. This mechanism of depolymerization is different than mechanisms such as those reported U.S. Pat. No. 6,238,837 (Fan) where the ratio of binder to IR absorber (carbon black in this instance) is 1:1 to favor ablation, or the use of acrylates to favor crosslinking of the binder as reported in U.S. Pat. No. 6,548,222 (Teng) or further yet, the use of sublimable dyes to interact with the exposing energy rather than the binder as reported in U.S. Pat. No. 5,994,026 (DeBoer, et al).

### Thermally Imageable Film Properties

The thermally imageable film remains transparent even when exposed to visible light of wavelengths of about 390 to 750 nm. Thus, the thermally imageable film is white light safe. Further, the thermally imageable film does not contain ultraviolet light sensitive material such as diazo-compounds and is therefore also insensitive to ultraviolet light (also referred to herein as UV radiation) of wavelengths of about 190 to 390 nm. The exclusion of diazo-compounds from the thermally imageable film also renders the thermally imageable film free of compounds that produce a gas upon heating, which results in formation of vesicular images. The thermally imageable film is also free of gas producing compounds typically used for laser ablative imaging.

Upon image-wise exposure to infrared (IR) thermal radiation (also referred to herein as IR laser radiation or laser thermal radiation), the thermally imageable film becomes opaque at the point of contact between the IR thermal radiation and the thermally imageable layer, thereby forming an opaque area on the thermally imageable layer. The opaque area is impermeable to ultraviolet light. Areas of the thermally imageable film not contacted by the IR thermal radiation remain transparent and permeable to ultraviolet light.

The opaque area of the thermally imageable film is the result of thermal degradation of the thermally degradable binder from a polymer to a monomer. Thermal degradation mechanisms of polymers are well known and include depolymerization, random scission, and side group elimination. In the present invention the thermally degradable polymer depolymerizes. Depolymerization, also known as unzipping, occurs mainly with polymers prepared from 1,1-disubstituted monomers. Unzipping may be initiated at a chain end or at a random site along the backbone. For instance, poly (methyl methacrylate) begins unzipping primarily at the chain ends, whereas poly α-methylstyrene) does so at random sites along the chain.

Thermal degradation does not occur until the temperature is sufficiently high to initiate degradation of the thermally degradable binder by depolymerization mechanisms. For example, exposure of a 1 to 2 g/m² coating of a thermally degradable binder with 300 mJ/cm² of 830 nm radiation increases the temperature of the coating to about 250° C. for approximately 1 to 2 microseconds. Where the thermally degradable binder is poly(methyl methacrylate), depolymerization begins at about 300° C. and is complete at about 400° C. Therefore, at a coating weight of about 6 g/m², from about 300-500 mJ of imaging energy is necessary to depolymerize the poly(methyl methacrylate) coating.

The energy required to generate enough heat to depolymerize the thermally degradable polymer is provided by an IR absorber that absorbs IR thermal radiation energy and converts it to heat. Without an IR absorber, the IR laser radiation would pass through the thermally imageable layer and no heat would be transferred to the thermally degradable binder of the thermally imageable film.

### Thermally Depolymerizable Binder

In the present invention, the thermally imageable film includes at least one thermally degradable binder. The thermally degradable binder can be a single polymer or a mixture of polymers that thermally degrade to smaller fragments such as oligomers or monomers.

Examples of suitable thermally degradable polymers include poly (methylmethacrylate), polystyrene, poly(ethyleneterephthalate), poly α-methylstyrene) and polyisobutylene. In one embodiment of the present invention, the thermally degradable polymer is poly (methylmethacrylate). Additional thermally degradable polymers include cellulosic resins such as hydroxypropylcellulose, cellulose nitrate, cellulose acetate hydrogen phthalate, cellulose acetate, cellulose acetate propionate, cellulose acetate butyrate, as well as polycarbonates, polyurethanes, polyesters, poly(vinyl acetate), polystyrene derivatives, and vinylpyrrolidone polymers.

The thermally degradable binder is typically present in an amount of from about 80 to 99.5 wt %. In an alternative embodiment, the thermally degradable binder is present in an amount of from about 85 to 97 wt %. And in yet another embodiment, the thermally degradable binder is present in an amount of from about 90 to about 94 wt %.

### Infrared Absorber

The present invention includes an infrared absorber (also referred to herein as an IR absorber, dye or pigment) that absorbs energy from the IR thermal radiation and converts it to heat.

The IR absorber of the present invention absorbs IR radiation in the range of about 750 nm to 1200 nm, the range of radiation commonly used for imaging thermally imageable elements. The IR absorber should not substantially absorb, scatter or refract ultraviolet radiation and/or white light. Consequently, IR absorbers that absorb IR radiation but not the ultraviolet and visible radiation are preferred.

Suitable IR dyes generally include azo dyes, squarilium dyes, croconate dyes, triarylamine dyes, thiazolium dyes, indolium dyes, oxonol dyes, oxaxolium dyes, cyanine dyes, merocyanine dyes, indocyanine dyes, indotricarbocyanine dyes, oxatricarbocyanine dyes, thiocyanine dyes, thiatricarbocyanine dyes, merocyanine dyes, cryptocyanine dyes, naphthalocyanine dyes, polyaniline dyes, polypyrrole dyes, polythiophene dyes, chalcogenopyryloarylidene and bis (chalcogenopyrylo) polymethine dyes, oxyindolizine dyes, pyrylium dyes, pyrazoline azo dyes, oxazine dyes, naphthoquinone dyes, anthraquinone dyes, quinoneimine dyes, methine dyes, arylmethine dyes, squarine dyes, oxazole dyes, croconine dyes, and porphyrin dyes. Dyes, especially dyes with a high extinction coefficient in the range of 750 nm to 1200 nm and with the appropriate absorption spectrum and solubility, are preferred. Absorbing dyes are disclosed in numerous publications, for example, EP 0,823,327 (Nagasaka); U.S. Pat. No. 4,973,572 (DeBoer); U.S. Pat. No. 5,244,771 (Jandrue); and U.S. Pat. No. 5,401,618 (Chapman), each of which are incorporated by reference. Additional examples of useful IR absorbers are listed in Chart 1 and in the Examples.

The amount of IR absorber in the thermally imageable film is generally sufficient to depolymerize the thermally degradable binder, which results in an opaque area after exposure to IR thermal radiation using about 170 to 570 mJ/cm².

Further, the amount of IR absorber in the thermally imageable film is generally sufficient to provide an optical density of at least 0.05 after exposure to IR thermal radiation. In one embodiment of the present invention the optical density is from about 0.5 to 5.0 after exposure to IR thermal radiation to resist ultraviolet radiation through the opaque areas for at least one minute. In another embodiment, the opaque areas of the film have an optical density of from about 0.05 to 4.0, from about 0.05 to 3.0, or from about 0.05 to 2.0. Further, in an alternative embodiment, the opaque area resists ultraviolet radiation through the opaque area for at least five minutes and in yet another embodiment the opaque area resists ultraviolet radiation through the opaque area for at least ten minutes.

In the present invention, the IR absorber is present in an amount of from about 0.5 to 20 wt % of the thermally imageable film. In an alternative embodiment, the IR absorber is present in an amount of from about 2 to 15 wt % of the thermally imageable film. And in yet another embodiment, the IR absorber is present in an amount of from about 6 wt % to about 10 wt % of the thermally imageable film.

Alternatively, a pigment could be used in the thermally imageable film rather than a dye. Because the pigment absorbs IR energy less efficiently than most dyes, however, greater amounts of the pigment within the thermally imageable film is necessary to achieve the optical density values that can be achieved using a dye.

### Additives

The thermally imageable film also includes additives that are chosen based on the final properties desired provided they are compatible with the other ingredients, do not strongly absorb the radiation used for thermal degradation, and do not otherwise interfere with depolymerization of the thermally degradable binder. Such additives are illustrated in U.S. patent application Ser. No. 10/282,994 filed Oct. 28, 2002 and Ser. No. 10/400,715 filed Mar. 27, 2003, both of which are incorporated herein by reference. Such additives include surfactants, dispersing agents, colorants, plasticizers, rheology modifiers, thermal polymerization inhibitors, tackifiers, antioxidants, antiozonants, fillers, or combinations thereof. The additives may also include humectants, biocides, pH adjusters, drying agents, defoamers, preservatives or combinations thereof.

### The Thermally Imageable Film as a Mask Precursor

The mixture of thermally degradable binder, IR absorber, and additives is coated from an aqueous or organic solvent onto a substrate to provide a transparent, thermally imageable film. This thermally imageable film may be used in a variety of applications including as a mask precursor for relief printing. The thermally imageable film can be coated directly on top of a substrate such as polyethylene terephthalate or polypropylene. Additional substrate materials include any material conventionally used to prepare a relief printing plate precursor. As used herein, the term relief printing plate precursor includes conventional flexographic printing plate precursors. Thus, in one embodiment of the present invention the mask precursor is a separate film. In an alternative embodiment the thermally imageable film is integral to a relief printing plate precursor such as a flexographic printing plate precursor.

### Substrates

The substrate comprises a support for the thermally imageable film that may be any material conventionally used to prepare mask precursors and/or relief printing plate precursors. The substrate is preferably strong, stable and flexible. It should also resist dimensional change under conditions of use so that the same mask or relief printing plate, when used at different times or in different environments, does not cause registration problems. This is particularly important where the printing process involves multiple color overlays (such as yellow, cyan, magenta and black) typically used in full color printing processes. Typically, the substrate can be any self-supporting material, including, for example, polymeric films such as polyethylene terephthalate, polystyrene, polyethylene, polypropylene, polycarbonate, polyamide and fluoropolymers, ceramics, metals, or stiff papers, or a lamination of any of these materials. Metal substrates include aluminum, zinc, titanium, and alloys thereof.

In one embodiment of the present invention, the substrate is a polyester film, such as, for example, a polyethylene terephthalate. The substrate is typically from about 2 to 4 mils thick.

Where the thermally imageable film is integral to the relief printing plate precursor, the substrate comprises a flexible support, which may be any flexible material conventionally used to prepare imageable elements useful as relief printing plate precursors. When the imageable element requires a back exposure, the substrate must be transparent to the radiation used for the back exposure.

### Use as a Relief Printing Plate Precursor

In one embodiment of the present invention, the thermally imageable film is integral to a relief printing plate precursor. In this particular embodiment, the thermally imageable film is coated directly onto a photoplymerizable layer of the relief printing plate precursor.

Suitable relief printing plate precursors may be prepared from photopolymerizable compositions, such as those compositions described in U.S. Pat. No. 4,323,637 (Chen, et al.) and pending U.S. patent application Ser. No. 10/282,995, both of which are incorporated herein by reference. The photopolymerizable compositions generally comprise an elastomeric binder, at least one monomer and a photoinitiator sensitive to ultraviolet radiation and/or visible light. The monomer or mixture of monomers must also be compatible with the thermally degradable binder of the thermally imageable film. Optionally, the photopolymerizable compositions can contain other additives depending on the final properties desired provided they are compatible with the other ingredients, do not strongly absorb the radiation used for polymerization, and do not otherwise interfere with polymerization of the photopolymerizable layer.

The photopolymerizable composition is coated onto a substrate to form a photopolymerizable layer. As used herein, the term “photopolymerizable” is intended to encompass systems that are photopolymerizable, photocrosslinkable, or both. Upon imagewise exposure to ultraviolet radiation and/or visible light, polymerization of the photopolymerizable layer occurs in the exposed areas. Treatment with a suitable developer removes the unexposed areas of the photopolymerizable layer leaving a relief printing plate that can be used, for example, for flexographic printing.

### Barrier Layer

The photopolymerizable layer may contain one or more compounds that can migrate to the surface of the photopolymerizable layer and possibly into adjacent layers such as the thermally imageable film. Low molecular weight compounds (i.e., molecular weight less than 30,000) are generally migratory. Low molecular weight compounds which are migratory are primarily liquids but can also include low melting solid materials. Examples of such migratory materials include monomers and plasticizers. The migratory materials tend to migrate over time if they are compatible with materials in adjacent layers. If such migration occurs into the thermally imageable film, then the IR sensitivity of the thermally imageable film can be compromised.

In conventional printing plate precursors having a photopolymerizable layer, a barrier layer such as that described in pending U.S. patent application Ser. No. 10/282,995, which is incorporated herein by reference, is placed on the photopolymerizable layer to minimize the migration of materials between the photopolymerizable layer and another layer as well as to shield the photopolymerizable layer from the atmospheric oxygen when the photopolymerizable layer is overall exposed to ultraviolet radiation and/or visible light. Similarly, in the printing plate precursor of U.S. Pat. Nos. 5,262,275 (Fan) and 5,719,009 (Fan), a barrier layer is required between the photopolymerizable layer and the layer containing IR absorbing materials to shield the photopolymerizable layer from atmospheric oxygen and to minimize migration of materials between the photopolymerizable layer and the layer containing IR absorbing materials.

Thus, in one embodiment of the present invention, an essentially oxygen-impermeable overcoat or barrier layer, which is soluble in the developer and transparent to the radiation used for the overall exposure, may be present over the photopolymerizable layer of the relief printing plate precursor. When present, the barrier layer is typically between the photosensitive layer and the thermally imageable film. The barrier layer inhibits the migration of oxygen into the photosensitive layer and can inhibit the migration of materials from the photosensitive layer into the thermally imageable film.

The relief printing plate precursor may also comprise a temporary coversheet over the thermally imageable film. The coversheet protects the thermally imageable film during storage and handling. Examples of suitable materials for the coversheet include thin films of polystyrene, polyethylene, polypropylene, polycarbonate, fluoropolymers, polyamide or polyester, which can be treated, coated or subbed with release layers.

### Methods of Making

The thermally depolymerizable binder, IR absorber, and additives can be combined to produce a clear, non-cloudy mixture having a pale green to yellow hue. This mixture is referred to herein as a thermally imageable composition. Typically these ingredients are dispersed or dissolved in a suitable coating solvent. The coating solvent can be an aqueous or organic solvent or mixtures thereof. The thermally imageable composition can then be coated over a surface of the substrate by conventional methods, such as spin coating, bar coating, gravure coating, roller coating, dip coating, air knife coating, hopper coating, blade coating, and spray coating. The coating weight of the thermally imageable film is typically from about 1 to 10 g/m² or alternatively from about 3 to 7 g/m².

A variety of conventional organic solvents can be used as the coating solvent for the thermally imageable film. Examples of suitable solvents for the present invention include alcohols such as methyl alcohol, ethyl alcohol, n- and i-propyl alcohols, n- and i-butyl alcohols and diacetone alcohol; ketones such as acetone, butyrolacetone, methyl ethyl ketone, methyl propyl ketone, diethyl ketone, and cyclohexanone; polyhydric alcohols and derivatives thereof such as ethylene glycol, ethylene glycol monomethyl ether or its acetate derivative, ethylene glycol monoethyl ether or its acetate derivative; ethylene glycol diethylether, ethylene glycol monobutyl ether or its acetate derivative, propylene glycol monomethyl ether or its acetate derivative, propylene glycol monoethyl ether or its acetate, propylene glycol monobutyl ether, 3-methyl-3-methoxybutanol, dioxolane; and other solvents such as N,N-dimethylformamide, methyl lactate, ethyl lactate, or tetrahydrofuran. However, for convenience during the drying process, solvents having a boiling point of between about 40° C. and about 160° C., or alternatively between about 60° C. and about 130° C., are typically used.

The solids content of the thermally imageable composition and coating solvent mixture is typically from about 2 to about 25 wt %, based on the weight of the solvent.

Selection of the coating solvent will also depend on the nature of the ingredients present in the thermally imageable composition. The solvent or mixture of solvents used in the present invention are typically chosen based upon the thermally degradable polymer used. For example, in one embodiment of the present invention the thermally degradable binder is poly (methylmethacrylate) and the solvent is tetrahydrofuran. In an alternative embodiment the thermally degradable binder is poly(vinylpropylene) and the coating solvent is water.

Drying of the coated thermally imageable composition to provide the thermally imageable film is usually carried out using heated air. The heated air temperature is preferably between about 30° C. and about 200° C., or alternatively between about 40° C. and about 120° C. Although other solvents may be used, water is frequently a good coating solvent for the thermally imageable film. The imageable film is typically dried by heating at from about 20° C. to 150° C. for from about 0.5 min to 5 min.

The air temperature may be held constant during the drying process, or may be gradually stepped up. Although the coating weight of the thermally imageable film will depend on the type of printing plate desired, the coating weight is typically from about 1 to 10 g/m² when applied to a flexographic printing plate precursor that is typically from about 0.046 to 0.250 inches thick before the thermally imageable film is coated on top.

Alternatively, the thermally imageable composition may be fed into an extruder and the thermally imageable composition extruded onto the substrate to form a film. The extruder performs the function of melting, mixing, deaerating and filtering the thermally imageable composition.

The barrier layer, if present, may be applied over the photopolymerizable layer of the relief printing plate precursor using conventional coating or lamination techniques, such as are described above. To prevent mixing of the layers during coating, the barrier layer is preferably coated from a solvent in which the photopolymerizable layer is essentially insoluble. Typical coating solvents for the barrier layer are water and aqueous solvents that contain small amounts of organic solvents such as methanol, ethanol, or i-propyl alcohol.

The thermally imageable film may be applied over the barrier layer if present, or directly on the photopolymerizable layer of the relief printing plate precursor if the barrier layer is not present, using conventional coating or lamination techniques, such as are described above.

The coversheet, if present, is typically laminated over the thermally film.

### Imaging and Processing

The coversheet, if present, is removed before imaging, typically by being peeled off. Imaging of the thermally imageable film may be carried out by well-known methods. The thermally imageable film may be imaged with a laser or an array of lasers emitting modulated near infrared or infrared radiation in a wavelength region that is absorbed by the absorber layer. Infrared radiation, especially infrared radiation in the range of about 800 nm to about 1200 nm, is typically used for imaging thermally imageable elements. Imaging is conveniently carried out with a laser emitting at about 830 nm, about 1056 nm, or about 1064 nm. Suitable commercially available imaging devices include image setters such as the CREO TRENDSETTER, the GERBER CRESCENT 42T, SCREEN PLATERITE model 4300 and model 8600 (Screen, Rolling Meadows, Chicago, Ill.), as well as the CDI CLASSIC and CDI COMPACT platesetters (Esko-Graphics, Vandalia, Ohio). Imaging with 1064 nm radiation has been found to be particularly advantageous.

Imaging of the thermally imageable film produces imaged and unimaged regions. The imaged regions will appear opaque while the unimaged regions will remain transparent on the thermally imageable film.

When the thermally imageable film is coated on a photopolymerizable layer of a relief printing plate precursor, following imaging of the thermally imageable film, the relief printing plate precursor is subjected to floodwise (overall or blanket) exposure through the exposed integral mask precursor with ultraviolet and/or visible radiation to which the photopolymerizable layer is sensitive, using light sources and procedures known in the art. Light sources include, for example, carbon arcs, mercury-vapor arcs, fluorescent lamps, electron flash units, electron beam units and photographic flood lamps. The most suitable sources of ultraviolet radiation are the mercury-vapor lamps, particularly the sun lamps. A standard radiation source is the SYLVANIA® 350 Blacklight fluorescent lamp (FR 48T12/350 VL/VHO/180, 115 w) which has an ultraviolet wavelength of emission around 354 nm. The radiation used for overall exposure is effectively blocked by the opaque, imaged regions of the thermally imageable film, but is at least partly transmitted by the transparent, non-imaged regions of the thermally imageable film.

Overall exposure forms a latent image in the photopolymerizable layer. The latent image consists of polymerized regions and unpolymerized regions.

The exposure level depends on the thickness of the photopolymerizable layer, its sensitivity to the radiation used for overall exposure, and the amount of radiation transmitted by the nonimaged regions of the thermally imageable film. However, the level of exposure is usually at least 0.1 mJ/cm². In one embodiment of the present invention, the level of exposure is at least 100 mJ/cm² of ultraviolet radiation and in yet another embodiment at least 300 mJ/cm² is used.

For thick relief printing plate precursors, such as those used to form flexographic printing plates, the process typically comprises a back exposure or backflash step. This is a blanket exposure through the substrate, using radiation to which the photopolymerizable layer is sensitive. Backflash exposure creates a shallow layer of photopolymerized material, or a floor, on the substrate side of the photopolymerizable layer. The floor improves adhesion between the photopolymerizable layer and the substrate and also establishes the depth of the relief image in the resulting relief printing plate.

Backflash exposure may be carried out before, after or during the other imaging steps. Preferably, it is carried out after imaging of the thermally imageable film and just prior to overall exposure. Any of the conventional radiation sources discussed above can be used for the backflash exposure step. Exposure time generally ranges from a few seconds up to about a minute.

Following overall exposure through the imaged thermally imageable film, the relief printing plate precursor is developed with a suitable developer. The thermally imageable film may either be removed prior to development of the relief printing plate precursor or may remain on the relief printing plate precursor and developed away too. Development is usually carried out at about room temperature. Development converts the latent image to an image by removing the unpolymerized or unexposed regions of the photopolymerizable layer.

The developers can be organic solvents, aqueous or semi-aqueous solutions, or water. The choice of the developer will depend primarily on the chemical nature of the photopolymerizable layer. Suitable organic solvent developers include aromatic or aliphatic hydrocarbon and aliphatic or aromatic halohydrocarbon solvents, or mixtures of such solvents with suitable alcohols. Other organic solvent developers have been disclosed in U.S. Pat. No. 5,354,645 (Schober), which is incorporated by reference herein. Suitable semi-aqueous developers usually contain water and a water miscible organic solvent and an alkaline material. Suitable aqueous developers usually contain water and an alkaline material. Other suitable aqueous developer combinations are described in U.S. Pat. No. 3,796,602 (Briney), which is incorporated by reference herein. In one embodiment of the present invention, the flexographic printing plate precursor is developed in a mixture of nonyl acetate and benzyl alcohol (OPTISOL rotary solution) or alternatively heptyl acetate and heptyl alcohol (OPTISOL in-line solution).

Development time can vary, but it is preferably in the range of from about 2 to 25 min. The developer can be applied in any convenient manner, including immersion, spraying, brush or roller application. Brushing aids can be used to remove the unpolymerized portions of photopolymerizable layer. However, washout is frequently carried out in an automatic processing unit which uses the developer and mechanical brushing action to remove the unexposed portions of the photopolymerizable layer to give a relief constituting the exposed image and the floor formed by the backside flask exposure.

Following development, the resulting relief printing plates are typically blotted or wiped dry, and then dried in a forced air or infrared oven. Drying times and temperatures may vary, however, typically the plate is dried for from about 60 to 120 min at about 60° C. High temperatures are not recommended because the substrate can shrink and this can cause registration problems.

The resulting relief printing plates are typically overall post-exposed to ensure that the photopolymerization process is complete and that the plate will remain stable during printing and storage. This post-exposure may be carried out with the same radiation source as overall exposure.

Detackification is an optional post-development treatment, which can be applied if the surface is still tacky, such tackiness not generally being removed in post-exposure. Tackiness can be eliminated by methods well known in the art, such as treatment with bromine or chlorine solutions. Such treatments have been disclosed in, for example, U.S. Pat. No. 4,400,459 (Greetzmacher); U.S. Pat. No. 4,400,460 (Fickes); and U.S. Pat. No. 4,906,551 (Hermann), each of which are incorporated by reference herein. Detackification can also be accomplished by exposure to radiation sources having a wavelength not longer than 300 nm, as disclosed in U.S. Pat. No. 4,806,506 (Gibson).

In one embodiment, the thermally imageable film can also be used in the preparation of flexographic printing plate precursors. When the thermally imageable film is coated on top of the flexographic printing plate precursor, the thermally imageable film is said to be integral to the flexographic printing plate precursor. Further, when the thermally imageable film is image-wise exposed to IR thermal radiation, the thermally imageable film forms opaque areas. The opaque areas mask the photopolymerizable layer underneath the thermally imageable layer. Because the imaged, thermally imageable film is integral to the flexographic printing plate precursor the disadvantages of separate or laminated masks, such as dirt entrapment and reduced resolution, are avoided.

The advantageous properties of this invention can be observed by reference to the following examples, which illustrate but do not limit the invention.

Although the present invention has been described with reference to particular embodiments, workers skilled in the art will recognize that changes may be made in form and detail without departing from the spirit and scope of the invention. In addition, the invention is not to be taken as limited to all of the details thereof as modifications and variations thereof may be made without departing from the spirit or scope of the invention.

### EXAMPLES

In the Examples, “coating solution” refers to the mixture of solvent or solvents and additives coated, even though some of the additives may be in suspension rather than in solution, and “total solids” refers to the total amount of nonvolatile material in the coating solution even though some of the additives may be nonvolatile liquids at ambient temperature. The indicated percentages are percentages by weight based on the total solids in the coating solution unless otherwise indicated.

### Glossary

| | |
|---|---|
| Infrared | IR Dye A: See Chart 1 |
| Absorbing | IR Dye B: See Chart 1 |
| Dye | IR Dye C: See Chart 1 |
| Infrared | RAVEN 1255 - a carbon black as supplied by |
| Absorbing | Columbian Chemical Company, Marietta, GA |
| Pigment | |
| Thermally | PMMA - (poly(methyl methacrylate)) powder |
| Degradable | average molecular weight ca. 15,000 as supplied by |
| Binder | Aldrich Chemical Company, Milwaukee, WI. |
| | Polystrene - catalogue number 44,114-7 as supplied |
| | by Aldrich Chemical Company. |
| | Polyisobutylene - as supplied by Aldrich Chemical |
| | Company. |
| | Poly (vinyl pyrrolidone) - powder average |
| | molecular weight ca. 10,000 as supplied by Aldrich |
| | Chemical Company. |
| | Cellulose acetate phthalate - as supplied by Aldrich |
| | Chemical Company. |
| | Poly(4-vinyl phenol) - as supplied by Aldrich |
| | Chemical Company. |
| | SD140A - a novolak resin from Borden Chemical, |
| | Louisville, Kentucky. |
| | SARAN F-310, a copolymer of vinylidene chloride |
| | and acrylonitrile as supplied by Dow Chemical |
| | Company, Midland, MI. |
| | Cellulose acetate propionate (CAP), average Mₙ ca. |
| | 25,000 by GPC as supplied by Aldrich Chemical |
| | Company. |
| | Cellulose acetate butyrate (CAB), average Mₙ ca. |
| | 30,000 by GPC as supplied by Aldrich Chemical |
| | Company. |
| | Cellulose acetate phthalate - as supplied by Aldrich |
| | Chemical Company. |
| Additives | SOLPERSE 5000 - a 100% active synergist agent as |
| | supplied by Avecia Inc., Charlotte, North Carolina. |
| | SOLPERSE 20000 - a polymer dispersant agent as |
| | supplied by Avecia Inc. |
| Solvent | Tetrahydrofuran (THF) as supplied by Aldrich |
| | Chemical Company. |
| | 1-methoxypropan-2-ol as supplied by Aldrich |
| | Chemical Company. |
| | Water |
| Relief Printing | CYREL flexographic printing plate, as supplied by |
| plate precursor/ | E.I. du Pont de Nemours and Company, Wilmington, |
| substrate | DE. |
| Lithographic | ARIES EXCEL positive working lithographic |
| printing plate | printing plate as supplied by Kodak Polychrome |
| precursor | Graphics, Norwalk, CT. |
| | VISTAR 360 negative printing plate, as supplied by |
| | by Kodak Polychrome Graphics |
| Developer | GOLDSTAR developer - a sodium metasilicate |
| Solution | developer as supplied by Kodak Polychrome |
| | Graphics. |
| | 955 developer as supplied by Kodak Polychrome |
| | Graphics. |
| | Perclene and butanol mixture as supplied by Aldrich |
| | Chemical Company. |
| Oven | Mathis Labdryer LTE Oven as supplied Werner |
| | Mathis, Switzerland. |
| Platesetter | CREO TRENDSETTER 3230 - a commercially |
| | available platesetter, using PROCOM PLUS |
| | software, operating at a wavelength of 830 nm and |
| | supplied by Creo Products Inc., Burnaby, BC, |
| | Canada. |
| Lightframe | OLIX A1 131 + light integrator as supplied by |
| | Olec Corporation Irvine, CA. |
| | CYREL 3040 light source, as supplied by E.I. du |
| | Pont de Nemours and Company. |
| Automated | MERCURY MARK V processor - an immersion |
| Developer | type processor as supplied by Kodak Polychrome |
| | Graphics. |
| | JAVIN PC32 Processor as supplied by Kodak |
| | Polychrome Graphics. |
| | CYREL Rotary sold by E.I. du Pont de Nemours |
| | and Company. |

Examples 1 to 7

The following thermally imageable compositions containing solutions of the components described in the table below in tetrahydrofuran (THF) were coated onto unsubbed polyester film by means of a wire wound bar. The concentrations of the thermally imageable compositions were selected to provide dry thermally imageable films having a coating weight of 6 gm⁻² for examples 1, 2 and 6, 10 gm⁻² for examples 4, 5 and 7 and 3 gm⁻² for example 3. The thermally imageable films were dried at 100° C. for 90 seconds in the Mathis oven.

| | Example | | | | | | |
|---|---|---|---|---|---|---|---|
| | 1 | 2 | 3 | 4 | 5 | 6 | 7 |
| Component | Parts by Weight | | | | | | |
| PMMA | 97 | 94 | 94 | 97 | 94 | 88 | 88 |
| IR Dye A | 3 | 6 | 6 | 3 | 6 | 12 | 12 |

Samples of each example were exposed on the CREO TRENDSETTER at 18W with drum speeds 55, 70, 85, 100, 115, 130, 145, 160, 175, 190 and 205 rpm, using an internal test pattern. This equates to 738, 579, 477, 406, 353, 312, 280, 254, 232, 213 and 198 mJcm⁻². Where the laser struck the thermally imageable film, the exposed area became opaque and yellowed. This was in contrast to the unexposed areas, which remained transparent and green. The minimum imaging energy density required to achieve maximum opacity, for each example is detailed in the table below.

| | Example | | | | | | |
|---|---|---|---|---|---|---|---|
| | 1 | 2 | 3 | 4 | 5 | 6 | 7 |
| Minimum imaging | 312 | 280 | — | 280 | 232 | 280 | 213 |
| energy required | | | | | | | |
| (mJcm⁻²) | | | | | | | |

Example 3 did not produce a full, opaque image at any exposure condition. A ghost image could be seen at 579 mJcm⁻².

Samples of examples 1, 4 and 5 were used as masks in the exposure of an ARIES EXCEL plate. The ARIES EXCEL plate, size 460×660×0.3 mm was exposed for 20 seconds, for examples 1 and 4, and for 45 seconds for example 5, through each mask using the OLIX A1 131+ light integrator. The printing plate precursor was then processed in a MERCURY MARK V processor containing GOLDSTAR developer (processing speed 1500 mm/min, developer temperature 22.5° C.). The areas of photopolymerizable layer exposed to the UV radiation, dissolved away in developer, but the areas protected by the opaque, yellowed image of the mask, resisted development. Thus, an accurate copy of the image was transferred to the printing plate precursor.

### Examples 8 to 16

The following thermally imageable compositions containing solutions of the components described in the table below in THF were coated onto unsubbed polyester film by means of a wire wound bar. The concentrations of the thermally imageable compositions were selected to provide dry thermally imageable films having a coating weight of 6 gm⁻² for examples 8, 9, 11, 12, 14 and 15 and 3 gm⁻² for examples 10, 13 and 16. The thermally imageable films were dried at 100° C. for 90 seconds in the Mathis oven.

| | Example | | | | | | | | |
|---|---|---|---|---|---|---|---|---|---|
| | 8 | 9 | 10 | 11 | 12 | 13 | 14 | 15 | 16 |
| Component | Parts by Weight | | | | | | | | |
| SARAN F- | 97 | 94 | 94 | 97 | 94 | 94 | | | |
| 310 | | | | | | | | | |
| IR Dye A | 3 | 6 | 6 | | | | | | |
| PMMA | | | | | | | 97 | 94 | 94 |
| IR Dye B | | | | 3 | 6 | 6 | 3 | 6 | 6 |

Samples of each example were exposed on the CREO TRENDSETTER at 18W with drum speeds 55, 70, 85, 100, 115, 130, 145, 160, 175, 190 and 205 rpm, using an internal test pattern. This equates to 738, 579, 477, 406, 353, 312, 280, 254, 232, 213 and 198 mJcm⁻². Where the laser struck the thermally imageable film, the coating became opaque and yellowed. This was in contrast to the unexposed areas, which remained transparent and green. The minimum imaging energy density required to achieve maximum opacity, for each example is detailed in the table below.

| | Example | | | | | | | | |
|---|---|---|---|---|---|---|---|---|---|
| | 8 | 9 | 10 | 11 | 12 | 13 | 14 | 15 | 16 |
| Minimum imaging | — | — | — | — | — | — | 477 | 254 | 280 |
| energy required | | | | | | | | | |
| (mJcm⁻²) | | | | | | | | | |

Examples 8 to 13 did not produce a full, opaque image at any exposure condition.

A sample of example 15 was used as a mask in the exposure of an ARIES EXCEL plate. The ARIES EXCEL plate, size 460×660×0.3 mm was exposed for 20 seconds through the mask using the OLIX A1 131+light integrator. The ARIES EXCEL plate was then processed in a MERCURY MARK V processor containing GOLDSTAR developer (processing speed 1750 mm/min, developer temperature 22.5° C.). The areas of the photopolymerizable layer exposed to the UV radiation, dissolved away in developer, but the areas protected by the opaque, yellowed image of the mask, resisted development. Thus, an accurate copy of the image was transferred to the ARIES EXCEL plate.

### Examples 17 to 28

The following thermally imageable compositions containing solutions of the components described in the table below in THF for examples 17 to 22, 1-methoxypropan-2-ol for examples 23 to 26 and water for examples 27 and 28, were coated onto unsubbed polyester film by means of a wire wound bar. The concentrations of the thermally imageable composition were selected to provide dry thermally imageable films having a coating weight of 6 gm⁻² for examples 17, 19, 21, 23, 25 and 27 and 3 gm⁻² for examples 18, 20, 22, 24, 26 and 28. The thermally imageable films were dried at 100° C. for 90 seconds in the Mathis oven.

| | Example | | | | | |
|---|---|---|---|---|---|---|
| | 17 & 18 | 10 & 20 | 21 & 22 | 23 & 24 | 25 & 26 | 27 & 28 |
| Component | Parts by Weight | | | | | |
| IR Bye B | 6 | 6 | 6 | 6 | 6 | |
| Polystyrene | 94 | | | | | |
| Poly- | | 94 | | | | |
| isobutylene | | | | | | |
| Cellulose | | | 94 | | | |
| acetate | | | | | | |
| phthalate | | | | | | |
| SD140A | | | | 94 | | |
| Polyvinyl | | | | | 94 | |
| (phenol) | | | | | | |
| Poly(vinyl | | | | | | 94 |
| pyrrolidone) | | | | | | |
| IR Dye C | | | | | | 6 |

TRENDSETTER at 18W with drum speeds 55, 70, 85, 100, 115, 130, 145, 160, 175, 190, 205, 220 and 235 rpm, using an internal test pattern. This equates to 738, 579, 477, 406, 353, 312, 280, 254, 232, 213, 198, 180 and 171 mJcm⁻². Where the laser struck the thermally imageable film, the thermally imageable film became opaque and yellowed. This was in contrast to the unexposed areas, which remained transparent. The minimum imaging energy density required to achieve maximum opacity, for each example is detailed in the table below.

| | Example | | | | | | | | | | | |
|---|---|---|---|---|---|---|---|---|---|---|---|---|
| | 17 | 18 | 19 | 20 | 21 | 22 | 23 | 24 | 25 | 26 | 27 | 28 |
| Minimum imaging | 477 | 579 | 579 | 579 | 232 | 180 | — | — | — | — | 171 | 171 |
| energy required | | | | | | | | | | | | |
| (mJcm⁻²) | | | | | | | | | | | | |

Examples 23 to 26 did not produce a full, opaque image at any exposure condition.

Samples of examples 21 and 27 were used as masks in the exposure of an ARIES EXCEL plate. The ARIES EXCEL plate, size 460×660×0.3 mm was exposed for 30 seconds through the masks using the OLIX A1 131+light integrator. The ARIES EXCEL plate was then processed in a MERCURY MARK V processor containing GOLDSTAR developer (processing speed 1750 mm/min, developer temperature 22.5° C.). The areas of photopolymerizable layer exposed to the UV radiation, dissolved away in developer, but the areas protected by the opaque image of the masks, resisted development. Thus, accurate copies of each image, were transferred to the ARIES EXCEL plate.

Another sample of example 22 was used as a mask in the exposure of a VISTAR 360 printing plate. The VISTAR 360 negative printing plate, size 460×660×0.3 mm, was exposed for 30 seconds through the mask OLIX A1 131+light integrator. The sample was then processed in a JAVIN PC32 processor containing 955 developer at a processing speed of 3 ft/min. The areas of photopolymerizable layer not exposed to the UV radiation (i.e., those areas protected by the opaque mask image), dissolved away in developer, but the areas exposed to the radiation resisted development. Thus, an accurate copy of the image was transferred to the VISTAR 360 negative printing plate.

### Example 29

A photopolymerizable layer is provided by removing an existing coversheet and release layer from the photopolymerizable layer of a CYREL flexographic printing plate precursor, type 67HLS. The photopolymerizable layer is the top layer on a support.

The thermally imageable composition from example 7 is applied onto the photopolymerizable layer using a wire wound Meyer bar, such that the dry thermally imageable coating weight is 8 gm⁻². The coating is dried at 70° C. for 7 minutes in a Mathis oven. A sample is then imagewise exposed on the CREO TRENDSETTER at 220 mJcm⁻², using an internal test pattern. Where the laser strikes the thermally imageable film, the coating becomes opaque.

The resulting flexographic printing plate precursor is then given a back flash exposure of 14 seconds on a CYREL 3040 light source, and is then given a top exposure of 2 minutes through the radiation opaque patterned mask without a vacuum. The exposed flexographic printing plate precursor is then developed in a CYREL rotary processor for 6 minutes using a 3:1 mixture (vol/vol) of perclene and butanol. The unexposed areas of the photopolymerizable layer and the opaque areas of the mask layer are removed, to form a flexographic printing plate. The flexographic printing plate is oven dried for one hour at 60° C. and is then simultaneously post exposed and finished in a CYREL 3040 light source for five minutes. On printing with the flexographic printing plate good images are obtained.

### Examples 30 to 32

The following thermally imageable compositions containing solutions of the components described in the table below in THF were coated onto unsubbed polyester film by means of a wire wound bar. The concentrations of the thermally imageable composition were selected to provide dry thermally imageable films having a coating weight of 6 gm⁻² for example 31 and 3 gm⁻² for examples 30 and 32. The coatings were dried at 100° C. for 90 seconds in the Mathis oven.

| | Example | | |
|---|---|---|---|
| | 30 | 31 | 32 |
| Component | Parts by Weight | | |
| CAP | 94 | | |
| CAB | | 94 | 94 |
| IR Dye B | 6 | 6 | 6 |

Samples of each example were exposed on the CREO TRENDSETTER at 18W with drum speeds 55, 70, 85, 100, 115, 130, 145, 160, 175, 190 and 205 rpm, using an internal test pattern. This equates to 738, 579, 477, 406, 353, 312, 280, 254, 232, 213 and 198 mJcm⁻². Where the laser struck the film, the coating became opaque and yellowed. This was in contrast to the unexposed areas, which remained transparent and green. The minimum imaging energy density required to achieve maximum opacity, for each example is detailed in the table below.

| | Example | | |
|---|---|---|---|
| | 30 | 31 | 32 |
| Minimum imaging | 406 | 406 | 477 |
| energy required | | | |
| (mJcm⁻²) | | | |

### Example 33

The following thermally imageable coating composition containing a solution of the components described in the table below in THF, was coated onto unsubbed polyester film, using a wire wound bar, such that the dry film coating weight was 7 gm⁻². The coating was dried at 105° C. for 3 minutes in a Mathis oven.

| | Example |
|---|---|
| | 33 |
| Component | Parts by Weight |
| CAP | 92.2 |
| RAVEN 1255 | 5.8 |
| SOLSPERSE 5000 | .05 |
| SOLSPERSE 20000 | 1.5 |

A sample of example 33 was exposed on the CREO TRENDSETTER at 18W with drum speeds 55, 70, 85, 100, 115, 130, 145, 160, 175, 190 and 205 rpm, using an internal test pattern. This equates to 738, 579, 477, 406, 353, 312, 280, 254, 232, 213 and 198 mJcm⁻². Where the laser struck the film, the coating became opaque. This was in contrast to the unexposed areas, which remained transparent and gray. The minimum imaging energy density required to achieve maximum opacity was 232 mJcm⁻².

Chart 1. IR Absorbers

| Identifier | Structure | Source |
|---|---|---|
| IR Dye A: Photothermal conversion material | 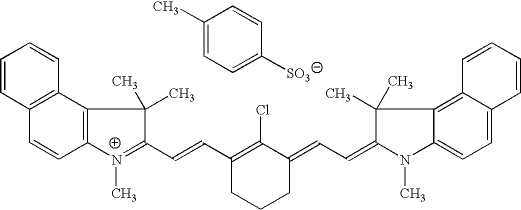 | Eastman Kodak, Rochester, NY, USA |
| IR Dye B: (KF654B) Photothermal conversion material | 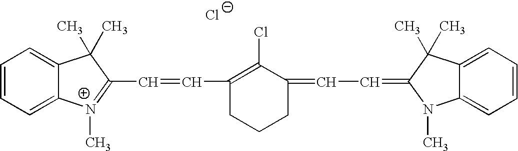 | Honeywell Specialty Chemicals, Morristown, NJ, USA |
| IR Dye C: Photothermal conversion material | 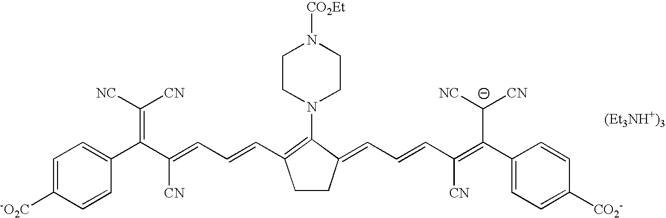 | Eastman Kodak, Rochester, NY, USA |

What is claimed is:

1. A thermally imageable film consisting essentially of:
about 80 to 99.5 wt % of at least one thermally degradable binder;
about 0.5 to 20 wt % of at least one infrared absorber; and
additives
that is transparent and remains transparent when exposed to white light of wavelengths of about 390 to 750 nm or ultraviolet light of wavelengths of about 190 to 390 nm and, upon image-wise exposure to IR thermal radiation, forms an opaque area where the thermal laser radiation contacts the thermally imageable film, the opaque area having an optical density of from about 0.5 to about 5.0 and being impermeable to ultraviolet light for at least 1 minute.

2. The thermally imageable film of claim 1, wherein the thermally imageable film is white light safe.

3. The thermally imageable film of claim 1, wherein the thermally imageable film is non-ablative.

4. The thermally imageable film of claim 1, wherein the thermally degradable binder is a depolymerizable polymer.

5. The thermally imageable film of claim 1, wherein the thermally degradable binder is selected from the group consisting of polymethyl methacrylate, polytetrafluoroethylene, polystyrene, poly(ethylene terephthalate), poly (alpha-methylstyrene), polyisobutylene and combinations thereof.

6. The thermally imageable film of claim 1, wherein the thermally degradable binder is polymethyl methacrylate.

7. The thermally imageable film of claim 1, wherein the thermally degradable binder is selected from the group consisting of hydroxypropylcellulose, cellulose nitrate, cellulose acetate hydrogen phthalate, cellulose acetate, cellulose acetate propionate, cellulose acetate butyrate, polycarbonates, polyurethanes, polyesters, poly(vinyl acetate), polystyrene derivatives, vinylpyrrolidone polymers and combinations thereof.

8. The thermally imageable film of claim 1, wherein the thermally imageable film comprises from about 85 to about 97 wt % thermally degradable binder.

9. The thermally imageable film of claim 1, wherein the thermally imageable film comprises from about 90 to about 94 wt % thermally degradable binder.

10. The thermally imageable film of claim 1, wherein the thermally imageable film comprises from about 3 to about 15 wt % infrared absorber.

11. The thermally imageable film of claim 1, wherein the thermally imageable film comprises from about 6 to about 10 wt % infrared absorber.

12. The thermally imageable film of claim 1, wherein the additives are selected from the group consisting of plasticizers, rheology modifiers, thermal polymerization inhibitors, tackifiers, colorants, surfactants, antioxidants, antiozonants, fillers and mixtures thereof.

13. The thermally imageable film of claim 1, wherein the opaque area has an optical density of from about 0.5 to about 4.0.

14. The thermally imageable film of claim 1, wherein the opaque area has an optical density of from about 0.5 to about 3.0.

15. The thermally imageable film of claim 1, wherein the opaque area has an optical density of from about 0.5 to about 2.0.

16. The thermally imageable film of claim 1, wherein the opaque area resists ultraviolet radiation for at least 5 minutes.

17. The thermally imageable film of claim 1, wherein the opaque area resists ultraviolet radiation for at least 10 minutes.

18. A mask precursor comprising:
a substrate; and
a thermally imageable film coated onto a substrate from a solvent consisting essentially of:
from about 80 to 99.5 wt % of at least one thermally degradable binder;
from about 0.5 to 20 wt % of at least one infrared absorber; and
additives
that is transparent and remains transparent when exposed to white light of wavelengths of about 390 to 750 nm or ultraviolet light of wavelengths of about 190 to 390 nm and, upon image-wise exposure to thermal laser radiation, forms an opaque area where the IR thermal radiation contacts the thermally imageable film the opaque area having an optical density of from about 0.5 to about 5.0 and being impermeable to ultraviolet light for at least 1 minute.

19. The mask precursor of claim 18, wherein the substrate is selected from the group consisting of polyester, polystyrene, polyethylene, polypropylene, polycarbonate, polyamide and fluoropolymers.

20. The mask precursor of claim 18, wherein the substrate comprises a flexographic printing plate precursor.

21. The mask precursor of claim 18, wherein the thermally imageable film has a coating weight of from about 1 gm⁻² to about 10 gm⁻².

22. A relief printing plate precursor comprising:
a thermally imageable film coated onto a substrate from a solvent consisting essentially of:
from about 80 to 99.5 wt % of at least one thermally degradable binder;
from about 0.5 to 20 wt % of at least one infrared absorber; and additives
that is transparent and remains transparent when exposed to white light of wavelengths of about 390 to 750 nm or ultraviolet light of wavelengths of about 190 to 390 nm and, upon image-wise exposure to thermal laser radiation, forms an opaque area where the IR thermal radiation contacts the thermally imageable film the opaque area having an optical density of from about 0.5 to about 5.0 and being impermeable to ultraviolet light for at least 1 minute.

23. The relief printing plate precursor of claim 22, wherein the thermally imageable film has a coating weight of from about 1 gm⁻² to about 10 gm^{-2.}

24. A method of making a mask comprising:
(a) providing a substrate;
(b) coating a thermally imageable film onto the substrate from a solvent consisting essentially of:
from about 80 to 99.5 wt % of at least one thermally degradable binder;
from about 0.5 to 20 wt % of at least one infrared absorber; and
additives
that is transparent and remains transparent when exposed to white light of wavelengths of about 390 to 750 nm or ultraviolet light of wavelengths of about 190 to 390 nm and, upon image-wise exposure to IR thermal radiation, forms an opaque area where the IR thermal radiation contacts the thermally imageable film the opaque area having an optical density of from about 0.5 to about 5.0 and being impermeable to ultraviolet light for at least 1 minute;
(c) image-wise exposing the thermally imageable film with IR thermal radiation to generate opaque areas impermeable to ultraviolet light where the IR thermal radiation contacts the thermally imageable film and leaving transparent areas permeable to ultraviolet light where the IR thermal radiation did not contact the thermally imageable film.

25. The method of making a mask of claim 24, wherein the substrate is selected from the group consisting of polyester, polystyrene, polyethylene, polypropylene, polycarbonate, polyamide and fluoropolymers.

26. The method of making a mask of claim 24, wherein the substrate comprises a flexographic printing plate precursor.

27. The method of making a mask of claim 24, wherein the thermally imageable film has a coating weight of from about 1 gm⁻² to about 10 gm⁻².

28. A method of making a relief printing plate comprising:
(a) providing a substrate;
(b) providing a ultraviolet light sensitive layer coated onto the substrate, the ultraviolet light sensitive layer having a photosensitive polymer;
(c) coating a thermally imageable film onto the ultraviolet light sensitive layer from a solvent consisting essentially of:
from about 80 to 99.5 wt % of the dry film of at least one thermally degradable binder;
from about 0.5 to 20 wt % of the dry film of at least one infrared; and
additives
that is transparent and remains transparent when exposed to white light of wavelengths of about 390 to 750 nm or ultraviolet light of wavelengths of about 190 to 390 nm and, upon image-wise exposure to IR thermal radiation, forms an opaque area where the IR thermal radiation contacts the thermally imageable film the opaque area having an optical density of from about 0.5 to about 5.0 and being impermeable to ultraviolet light for at least 1 minute;
(d) image-wise exposing the thermally imageable film with IR thermal radiation to generate opaque areas impermeable to ultraviolet light where the IR thermal radiation contacts the thermally imageable film and leaving transparent areas permeable to ultraviolet light where the IR thermal radiation does not contact the thermally imageable film;
(e) exposing the ultraviolet light sensitive layer to flood ultraviolet light exposure wherein the ultraviolet light permeates the transparent areas of the thermally imageable film to cure areas of the ultraviolet light sensitive layer underneath the transparent areas and wherein the opaque areas mask the ultraviolet light such that areas of the ultraviolet light sensitive layer underneath the opaque areas of the thermally imageable film do not cure;
(f) developing the ultraviolet light sensitive layer.

29. The method of making a relief printing plate of claim 28, wherein the exposed thermally imageable film is removed prior to developing the ultraviolet light sensitive layer.

30. The method of making a relief printing plate of claim 28, wherein the thermally imageable film has a coating weight of from about 1 gm⁻² to about 10 gm⁻².
